(19) United States
(12) Patent Application Publication
(10) Pub. No.: US 2011/0041897 A1
(43) Pub. Date: Feb. 24, 2011

(54) PHOTOVOLTAIC MODULES CONTAINING PLASTICIZED INTERMEDIATE LAYER FILMS WITH HIGH ALKALI TITRE

(75) Inventor: Bernhard Koll, St. Augustin (DE)

Correspondence Address: MILLEN, WHITE, ZELANO & BRANIGAN, P.C., 2200 CLARENDON BLVD., SUITE 1400, ARLINGTON, VA, 22201, US

(73) Assignee: Kuraray Europe GmbH, Frankfurt (DE)

(21) Appl. No.: 12/990,316

(22) PCT Filed: Apr. 16, 2009
(86) PCT No.: PCT/EP09/54511

§ 371 Date: Oct. 29, 2010

(30) Foreign Application Priority Data
Apr. 30, 2008 (DE) 102008001507.5

(51) Int. Cl. H01L 31/048

(52) U.S. Cl. 136/251; 29/890.033

(57) ABSTRACT

The invention relates to the use of plasticizer-containing films based on polyvinyl acetal and having a high alkali titre for the production of photovoltaic modules.

### TECHNICAL FIELD

The invention relates to the production of photovoltaic modules using plasticizer-containing films based on polyvinyl acetal having a high alkali titre in order to avoid corrosion at the photosensitive semiconductor layers.

### PRIOR ART

Photovoltaic modules consist of a photosensitive semiconductor layer that is provided with a transparent covering as a protection against external effects. As photosensitive semiconductor layer, monocrystalline solar cells or supported polycrystalline, thin semiconductor layers can be used. Thin-film solar modules consist of a photosensitive semiconductor layer applied to a substrate, such as a transparent sheet or a flexible support film, by means of for example evaporation coating, chemical vapour deposition, sputtering, or wet deposition.

Both systems are often laminated between a glass panel and a rigid, back covering panel made for example of glass or plastics by means of a transparent adhesive.

The transparent adhesive must completely enclose the photosensitive semiconductor layer and its electrical interconnections, must be UV stable and moisture insensitive, and must be completely bubble-free after the lamination process.

As transparent adhesive, thermosetting casting resins or crosslinkable, ethylene vinyl acetate-(EVA)-based systems are often used, as disclosed for example in DE 41 22 721 C1 or DE 41 28 766 A1. In the uncured state, these adhesive systems can be adjusted to such a low viscosity that they enclose the solar cell units in a bubble-free manner. After addition of a curing or crosslinking agent, a mechanically robust adhesive layer is obtained. A disadvantage of these adhesive systems is that during the curing process, aggressive substances, such as acids, which may destroy the photosensitive semiconductor layers, in particular thin-film modules, are often released. In addition, some casting resins tend to form bubbles or delaminate after a few years as a result of UV radiation.

An alternative to thermosetting adhesive systems is the use of plasticizer-containing films based on polyvinyl acetals, such as polyvinyl butyral (PVB) known from the manufacturing of laminated glass. The solar cell units are covered with one or more PVB films, and the films are bonded with the desired covering materials to form a laminate under elevated pressure and temperature.

Methods for the production of solar modules using PVB films are known for example from DE 40 26 165 C2, DE 42 278 60 A1, DE 29 237 70 C2, DE 35 38 986 02, or U.S. Pat. No. 4,321,418. The use of PVB films in solar modules as laminated safety glass is disclosed for example in DE 20 302 045 01, EP 1617487 A1, and DE 35 389 86 C2. These documents, however, do not contain any information about the mechanical, chemical, and electrical properties of the PVB films used.

The electrical properties of the films in particular have become more and more important with increasing efficiency of the photosensitive semiconductor layers and global distribution of solar modules. Loss of charge or even short circuits of the semiconductor layer must also be avoided under extreme weather conditions, such as tropical temperatures, high humidity, or strong UV radiation, over the entire lifetime of the module. In accordance with CEI 61215, photovoltaic modules are subjected to numerous tests (damp heat test, wet leakage current test) in order to reduce leakage currents of the modules.

It is known that the electrical resistance of PVB films declines sharply with increasing moisture content, which strongly favours the occurrence of leakage currents in photovoltaic modules. In the edge region of the photovoltaic module, the films, as encapsulation material, are exposed and subjected to ambient conditions, such as high ambient humidity. Here, the water content of the films in the edge region can strongly increase and take on values up to the equilibrium moisture content (approx. 3% by weight). The increased water content in the edge region of the film strongly reduces the electrical resistance thereof in this region. The water content does decrease again towards the middle of the film, but in order to avoid leakage currents, the photosensitive semiconductor layers can therefore not be placed all the way into the edge region of the film or module. This reduces the surface density and consequently the current efficiency of the module.

Solar cells, in particular photosensitive semiconductor layers of thin-film solar modules, for example based on CIS (copper/indium/(di)selenide) or copper/indium/gallium/sulphide/selenide (CIGS), or the thin layers (TCO: transparent conductive oxide) used as electric conductors are susceptible to chemical corrosion. The encapsulation material must therefore be as chemically inert as possible and should contain no aggressive chemical additives, such as curing agents, crosslinkers or primers. The presence of water or acid traces should also be avoided.

### TECHNICAL OBJECT

The object of the present invention was therefore to provide plasticizer-containing films based on polyvinyl acetal having low susceptibility for corrosion of the photosensitive semiconductor layers or electric conductors used.

### TECHNICAL SOLUTION

It was found that films based on polyvinyl acetals having a high alkali titre exhibit reduced susceptibility for corrosion of the photosensitive semiconductor layers or electric conductors used.

Without being bound to the correctness of this theory, the reduced susceptibility for corrosion may be attributed to the fact that the higher alkalinity of the PVB film (accompanied by an increased alkali titre) neutralises acids released during ageing processes that would trigger the destruction of acid-sensitive semiconductor layers without neutralisation.

### ILLUSTRATION OF THE INVENTION

The present invention therefore relates to photovoltaic modules comprising a laminate of

a) a transparent front covering
b) one or more photosensitive semiconductor layers
c) at least one plasticizer-containing film based on polyvinyl acetal, and
d) a back covering,
the plasticizer-containing film based on polyvinyl acetal having an alkali titre of more than 5.

### BEST EMBODIMENT OF THE INVENTION

The films used in accordance with the invention preferably therefore exhibit a specific alkalinity, expressed as an alkali titre, that may be more than 10, preferably more than 15 and in particular more than 20, 30 or 40. A maximum alkali titre of 100 should not be exceeded.

As described hereinafter, the alkali titre is established by back titration of the film and can be adjusted by adding alkaline substances, for example metal salts of organic carboxylic acids having 1 to 15 carbon atoms, in particular alkaline salts or alkaline earth salts such as magnesium or potassium acetate or NaOH, KOH or Mg(OH)₂. The alkaline compound is normally used at a concentration of 0.005 to 2% by weight, in particular 0.05 to 1% by weight, based on the entire mixture.

The avoidance of acid traces when producing the material is a further possibility for reducing the susceptibility to corrosion of the photosensitive semiconductor layers of the films used in accordance with the invention. Films of this type are generally produced by extrusion at increased temperatures, whereby the polymer material or plasticizer may undergo thermal decomposition. Furthermore, the residual acetate groups of the polyvinyl acetal may be cleaved by diffused water, whereby ethanoic acid is released. In both cases acid traces are produced, which may attack the photosensitive semiconductor layers.

The films used according to the invention preferably exhibit, at an ambient humidity of 85% RH at 23° C., a resistivity of at least 1E+11 ohm*cm, preferably at least 5E+11 ohm*cm, preferably 1E+12 ohm*c, preferably 5E+12 ohm*cm, preferably 1E+13, preferably 5E+13 ohm*cm, preferably 1E+14 ohm*cm.

In order to produce polyvinyl acetal, polyvinyl alcohol is dissolved in water and acetalised with an aldehyde, such as butyraldehyde with the addition of an acid catalyst. The polyvinyl acetal produced is separated, washed neutral, optionally suspended in an alkali aqueous medium, and then washed neutral again and dried.

The acid used for acetalisation must be neutralised again once the reaction has ended. An excess of base (for example NaOH, KOH or Mg(OH)₂) is used, thus increasing the alkali titre and making it possible to dispense with the addition of the alkaline substance, either completely or in part.

The polyvinyl alcohol content of the polyvinyl acetal may be adjusted by the amount of the aldehyde used during acetalisation. It is also possible to perform the acetalisation using other or additional aldehydes having 2-10 carbon atoms (for example valeraldehyde).

The films based on plasticizer-containing polyvinyl acetal preferably contain uncrosslinked polyvinyl butyral (PVB) obtained by acetalising polyvinyl alcohol with butyraldehyde.

The use of crosslinked polyvinyl acetals, in particular crosslinked polyvinyl butyral (PVB), is also possible. Suitable crosslinked polyvinyl acetals are described for example in EP 1527107 B1 and WO 2004/063231 A1 (thermal self-crosslinking of carboxyl group-containing polyvinyl acetals), EP 1606325 A1 (polyvinyl acetals crosslinked with polyaldehydes), and WO 03/020776 A1 (polyvinyl acetals crosslinked with glyoxylic acid). The disclosure of these patent applications is fully incorporated herein by reference.

Terpolymers of hydrolysed vinyl acetate/ethylene copolymers can also be used as polyvinyl alcohol within the scope of the present invention. These compounds are normally hydrolysed to more than 98 mol % and contain 1 to 10% by weight of ethylene-based units (for example type “Exceval” from Kuraray Europe GmbH).

Copolymers hydrolysed from vinyl acetate and at least a further ethylenically unsaturated monomer may also be used as polyvinyl alcohol within the scope of the present invention.

Within the scope of the present invention the polyvinyl alcohols may be used in pure form or as a mixture of polyvinyl alcohols with different degrees of polymerization or hydrolysation.

Polyvinyl acetals contain in addition to the acetal units also units resulting from vinyl acetate and vinyl alcohol. The polyvinyl alcohol content of the polyvinyl acetals used in accordance with the invention is preferably less than 22% by weight, 20% by weight or 18% by weight; less than 16% by weight or 15% by weight, and in particular less than 14% by weight. The polyvinyl alcohol content should not fall below 12% by weight.

The polyvinyl acetate content of the polyvinyl acetal used in accordance with the invention is preferably below 3% by weight or below 1% by weight, particularly preferably below 0.75% by weight, more particularly preferably below 0.5% by weight and in particular below 0.25% by weight.

The degree of acetalisation can be calculated from the polyvinyl alcohol content and the residual acetate content.

The films preferably have a plasticizer content of a maximum of 40% by weight, 35% by weight, 32% by weight, 30% by weight, 28% by weight, 26% by weight, 24% by weight or 22% by weight, whereby for reasons of the processability of the film, the plasticizer content should not fall below 15% by weight (in each case based on the total film formulation). Films or photovoltaic modules according to the invention can contain one or more plasticizers.

Suitable plasticizers for the films used in accordance with the invention are one or more compounds selected from the following groups:
esters of multivalent aliphatic or aromatic acids, for example dialkyl adipates such as dihexyl adipate, dioctyl adipate, hexylcyclohexyl adipate, mixtures of heptyl and nonyl adipates, diisononyl adipate, heptylnonyl adipate and esters of adipic acid with cycloaliphatic or ether compound-containing ester alcohols, dialkyl sebacates such as dibutyl sebacate and esters of sebacic acid with cycloaliphatic or ether compound-containing ester alcohols, esters of phthalic acid such as butylbenzyl phthalate or bis-2-butoxyethyl phthalate,
esters or ethers of multivalent aliphatic or aromatic alcohols or oligoether glycols having one or more unbranched or branched aliphatic or aromatic substituents, such as esters of di-, tri- or tetraglycols having linear or branched aliphatic or cycloaliphatic carboxylic acids; Examples of the latter group may include diethylene glycol-bis-(2-ethyl-hexanoate), triethylene glycol-bis-(2-ethyl-hexanoate), triethylene-glycol-bis-(2-ethylbutanoate), tetraethylene glycol-bis-n-heptanoate, triethylene glycol-bis-n-heptanoate, triethylene glycol-bis-n-hexanoate, tetraethylene glycol-dimethyl ether and/or dipropylene glycol benzoate.
Phosphates having aliphatic or aromatic ester alcohols, such as tris(2-ethylhexyl)phosphate (TOF), triethyl phosphate, diphenyl-2-ethylhexyl phosphate, and/or tricresyl phosphate.
Esters of citric acid, succinic acid and/or fumaric acid.

Compounds that are particularly suitable for use as plasticizers for the films used in accordance with the invention include one or more of those selected from the following group: di-2-ethylhexyl sebacate (DOS), di-2-ethylhexyl adipate (DOA), dihexyl adipate (DHA), dibutyl sebacate (DBS), triethylene glycol-bis-n-heptanoate (307), tetraethylene glycol-bis-n-heptanoate (407), triethylene glycol-bis-2-ethyl hexanoate (3GO or 3G8), tetraethylene glycol-bis-n-2-ethyl hexanoate (4GO or 4G8), di-2-butoxy-ethyl-adipate (DBEA), di-2-butoxyethoxyethyl adipate (DBEEA), di-2-butoxyethyl sebacate (DBES), di-2-ethylhexyl phthalate (DOP), di-isononyl phthalate (DINP), triethylene glycol-bis-isononanoate, triethylene glycol-bis-2-propyl hexanoate, tris(2-ethylhexyl)phosphate (TOF), diisononylcyclohexane dicarboxylic acid ester (DINCH) and dipropylene glycol benzoate.

Particularly suitable as plasticizers for the films used in accordance with the invention are plasticizers, the polarity of which, expressed by the formula 100×O/(C+H), is less than/equal to 9.4; O, C, and H representing the number of oxygen, carbon, and hydrogen atoms in the respective molecule. Table 1 below shows plasticizers applicable according to the invention and polarity values thereof in accordance with the formula 100×O/(C+H).

TABLE 1

| Name | Polarity Value |
|---|---|
| di-2-ethylhexyl sebacate (DOS) | 5.3 |
| diisononylcyclohexane dicarboxylic | 5.4 |
| acid ester (DINCH) | |
| di-2-ethylhexyl adipate (DOA) | 6.3 |
| di-2-ethylhexyl phthalate (DOP) | 6.5 |
| triethylene glycol-bis-2-propyl | 8.6 |
| hexanoate | |
| triethylene glycol-bis-i-nonanoate | 8.6 |
| di-2-butoxyethyl sebacate (DBES) | 9.4 |
| triethylene glycol-bis-2-ethyl | 9.4 |
| hexanoate (3G8) | |

Furthermore, the ion mobility, which might depend on the water content of the film, and hence the resistivity can be affected by the addition of SiO₂, in particular pyrogenic silicic acid. The plasticizer-containing films based on polyvinyl acetal preferably contain 0.001 to 15% by weight, preferably 2 to 5% by weight of SiO₂.

Furthermore, the films according to the invention may also additionally contain conventional additives, such as oxidation stabilizers, UV stabilizers, colourants, pigments and non-stick agents.

The production and composition of films based on polyvinyl acetals is described in principle for example in EP 185 863 B1, EP 1 118 258 B1, WO 02/102591 A1, EP 1 118 258 81, or EP 387 148 B1.

The lamination of the photovoltaic modules occurs by fusing the films, so that a bubble-free and waviness-free enclosure of the photosensitive semiconductor layer is obtained with the films.

In one variant of the photovoltaic modules according to the invention, the photosensitive semiconductor layers are applied to the covering d) (for example by evaporation coating, chemical vapour deposition, sputtering, or wet deposition) and bonded to the transparent front covering a) by means of a film c).

In another variant, the photosensitive semiconductor layers are applied to the transparent front covering a) and bonded to the back covering d) by means of the film c).

Alternatively, the photosensitive semiconductor layers can be embedded between two films c) and bonded to the coverings a) and d) in this manner.

The thickness of the films based on plasticizer-containing polyvinyl acetal is usually 0.38, 0.51, 0.76, 1.14, 1.52, or 2.28 mm.

During the lamination process, films used according to the invention fill the voids existing at the photosensitive semiconductor layers or the electrical connections thereof.

The transparent front covering a) normally consists of glass or PMMA. The back covering d) (so-called back sheet) of the photovoltaic module according to the invention can consist of glass, plastic, or metal or composites thereof, one of the supports possibly being transparent. It is also possible to design one or both of the coverings as laminated glass (i.e. as laminate made of at least two glass panels and at least one PVB film) or as insulation glass with a gas interspace. Naturally, combination of these measures is also possible.

The photosensitive semiconductor layers used in the modules do not need to have any special properties. Monocrystalline, polycrystalline or amorphous systems can be used.

In case of thin-film solar modules, the photosensitive semiconductor layer is directly applied to the support. An encapsulation is not possible here. For this reason, the composite is assembled from a support (for example the back covering) with the photosensitive semiconductor layer and the transparent front covering using at least one sandwiched plasticizer-containing film based on polyvinyl acetal according to the invention and bonded by means of this film at an elevated temperature. Alternatively, the photosensitive semiconductor layer can be applied to the transparent front covering as support and bonded to the back covering by means of at least one sandwiched plasticizer-containing film based on polyvinyl acetal according to the invention.

For lamination of the composite thus obtained, the methods known to those skilled in the art can be used with or without prior making of a pre-laminate.

So-called autoclave processes are performed at an elevated pressure of approximately 10 to 15 bar and temperatures of 130 to 145° C. over the course of approximately 2 hours. Vacuum bag or vacuum ring methods, for example according to EP 1 235 683 B1, operate at approximately 200 mbar and 130 to 145° C.

Vacuum laminators are preferably used for the production of the photovoltaic modules according to the invention. They consist of a heatable and evacuateable chamber, wherein laminated glasses may be laminated within 30-60 minutes. Reduced pressures of 0.01 to 300 mbar and temperatures of 100 to 200° C., in particular 130-160° C., have proven to be of value in practice.

Alternatively, a composite assembled as described above can be pressed into a module according to the invention between at least one pair of rollers at a temperature of 60 to 150° C. Installations of this kind are known for the production of laminated glasses and usually have at least one heating tunnel upstream or downstream from the first pressing apparatus in installations having two pressing apparatuses.

### INDUSTRIAL APPLICATION

The invention further relates to the use of plasticizer-containing films based on polyvinyl acetal, having an alkali titre of more than 5 or being constructed in accordance with the preferred embodiments mentioned, for the production of photovoltaic modules.

Photovoltaic modules according to the invention can be used as facade elements, roof surfaces, winter garden coverings, sound-insulating walls, balcony or balustrade elements, or as components of window surfaces.

### WAY(S) TO CARRY OUT THE INVENTION

### Measuring Procedures

The measurement of the volume resistivity of the film is performed in accordance with DIN IEC 60093 at a defined temperature and ambient humidity (23° C. and 85% RH) after the film has been conditioned for at least 24 h under these conditions. For the execution of the measurement, a plate electrode of type 302 132 from the company Fetronic GmbH and an instrument for resistivity measurement ISO-Digi 5 kV from the company Amprobe was used. The testing voltage was 2.5 kV, the wait time after application of the testing voltage until acquisition of measured data was 60 sec. In order to guarantee sufficient contact between the flat plates of the measuring electrode and the film, the surface roughness Rz of the film should not be greater than 10 mm when measuring in accordance with DIN EN ISO 4287; i.e. the original surface of the PVB film has to be smoothed by thermal reembossing prior to the resistivity measurement, if necessary.

The polyvinyl alcohol and polyvinyl alcohol acetate contents of the polyvinyl acetals were determined in accordance with ASTM D 1396-92. Analysis of the metal ion content took place by means of atomic absorption spectroscopy (AAS).

The water or moisture content of the films is determined by the Karl Fischer method. This method can be carried out both on the unlaminated film and on a laminated photovoltaic module depending on the distance of the film from the edge.

Alkali Titre

3 to 4 g of the plasticizer-containing polyvinyl acetal film are dissolved overnight in a magnetic stirrer in 100 ml of a mixture of ethanol/THF (80:20). For this purpose 10 ml of a diluted hydrochloric acid (c=0.01 mol/litre) are added and then titrated potentiometrically with a solution of tetrabutylammonium hydroxide (TBAH) in 2-propanol (c=0.01 mol/litre) using a titroprocessor against a blank. The alkali titre is calculated as follows:

Alkali titre=ml HCl per 100 g of a sample=(consumption of TBAH blank−TBAH sample×100 by weight of the sample in g.)

The damp heat test is carried out in accordance with CEI 61646.

### EXAMPLES

Substrate gasses measuring 30×30 cm and having functionally contacted thin-film cells (CIS) deposited thereon were bonded to a cover glass by PVB films in the laminating process. Following a first light soak treatment (equilibration), the starting efficiency (photocurrent efficiency) of the test modules was established. Equilibration was carried out again after 1000 h of damp heat loading (85% RH, 85° C.) and the photocurrent efficiency was established.

The efficiency of photovoltaic modules may decrease as a result of effects at the edge, for example the penetration of moisture. This affects the modules according to the invention and the comparative modules to the same extent.

Corrosion effects may also occur as a function of the alkalinity of the film. Tables 2 and 3 show that modules according to the invention do exhibit a loss in efficiency, but this is considerably lower than that of modules comprising films having a low alkali titre. This effect can be improved yet further by the presence of SiO₂.

The amounts detailed in tables 2 and 3 are given in % by weight, based on the sum of PVB and plasticizer. 3G8 is triethylene glycol-bis-2-ethyl hexanoate, AEROSIL 130 and TINUVIN 328 are commercial products from Evonik Degussa GmbH or CIBA. The loss in efficiency is given in % for a CIS module following a 1000 h damp heat test and volume resistivity is given in ohms accordance with DIN CEI 60093 for a film climatised at 23° C./85% RH (as described above).

TABLE 2

| | Example: | | | |
|---|---|---|---|---|
| | VB1 | B1 | VB2 | B2 |
| | Low | With | High AT | 2% |
| | alkali | 250 ppm | from | SiO₂, |
| Brief description | titre | NaAc | PVB | low AT |
| PVB | 76 | 76 | 76 | 78 |
| 3G8 | 24 | 24 | 24 | 22 |
| AEROSIL 130 | 0 | 0 | 0 | 2 |
| TINUVIN 328 | 0.15 | 0.15 | 0.15 | 0.15 |
| *sodium acetate | 0 | 0.025 | 0 | 0 |
| MgAc2*4H2O | 0 | 0 | 0 | 0 |
| PVOH in PVB | 18.0 | 18.0 | 18.2 | 20.3 |
| Alkali titre PVB | 5 | 5 | 22 | 7 |
| Alkali titre film | 3 | 27 | 17 | 0 |
| Efficiency loss | 34% | 16% | 21% | 27% |
| Volume resistivity | 3.9E+11 | 2.5E+11 | 3.2E+11 | 4.5E+12 |

TABLE 3

| | Example: | |
|---|---|---|
| | B4 | B3 |
| | 2% SiO₂, | 2% SiO₂, |
| Brief description | high AT | high AT |
| PVB | 78 | 78 |
| 3G8 | 22 | 22 |
| AEROSIL 130 | 2 | 2 |
| TINUVIN 328 | 0.15 | 0.15 |
| *sodium acetate | 0.05 | 0 |
| MgAc2*4H2O | 0 | 0.05 |
| PVOH in PVB | 20.3 | 20.3 |
| Alkali titre PVB | 7 | 7 |
| Alkali titre film | 36 | 24 |
| Efficiency loss | 12% | 14% |
| Volume resistivity | 3.2E+12 | 6.5E+12 |

1. A photovoltaic module comprising a laminate of
a) a transparent front covering
b) one or more photosensitive semiconductor layers
c) at least one plasticizer-containing film based on polyvinyl acetal, and
d) a back covering,
characterised in that
the plasticizer-containing film based on polyvinyl acetal c) has an alkali titre of more than 5.

2. The photovoltaic module according to claim 1, characterised in that the plasticizer-containing films based on polyvinyl acetal c) have a plasticizer content of a maximum of 40% by weight.

3. The photovoltaic module according to claim 1, characterised in that the plasticizer-containing films based on polyvinyl acetal c) have an electrical volume resistivity of more than 1E11 ohm*cm in an ambient climate of 85% RH/23° C.

4. The photovoltaic module according to claim 1, characterised in that the polyvinyl acetal has a polyvinyl acetate content of less than 3% by weight.

5. The photovoltaic module according to claim 1, characterised in that the polyvinyl acetal has a polyvinyl alcohol content of less than 22% by weight.

6. The photovoltaic module according to claim 1, characterised in that the plasticizer-containing films based on polyvinyl acetal c) contain a metal salt of a carboxylic acid having 1 to 15 carbon atoms as an alkaline compound.

7. The photovoltaic module according to claim 1, characterised in that the plasticizer-containing film based on polyvinyl acetal contains 0.001 to 5% by weight of SiO₂.

8. The photovoltaic module according to claim 1, characterised in that one or more photosensitive semiconductor layers b) are applied to a transparent front covering a) and are bonded by at least one plasticizer-containing film based on polyvinyl acetal c) to the rear covering d).

9. The photovoltaic module according to claim 1, characterised in that one or more photosensitive semiconductor layers b) are applied to a rear covering d) and are bonded by at least one plasticizer-containing film based on polyvinyl acetal c) to the transparent front covering a).

10. The photovoltaic module according to claim 1, characterised in that one or more photosensitive semiconductor layers b) are embedded between two films c) and bonded to the coverings a) and d).

11. A method of producing a photovoltaic module comprising bringing together as a laminate:
a) a transparent front covering
b) one or more photosensitive semiconductor layers
c) at least one plasticizer-containing film based on polyvinyl acetal, and
d) a back covering,
wherein said plasticizer-containing film based on polyvinyl acetal has an alkali titre of more than 5.

12. A façade element, roof surface, winter garden covering, sound-insulating wall, balcony or balustrade element, or window surface comprising a photovoltaic module according to claim 1.
